(19) United States
(12) Patent Application Publication
(10) Pub. No.: US 2006/0159848 A1
(43) Pub. Date: Jul. 20, 2006

(54) Method of making wear-resistant components

(76) Inventors: Yucong Wang, West Bloomfield, MI (US); Ronghua Wei, San Antonio, TX (US)

Correspondence Address: GENERAL MOTORS CORPORATION;LEGAL STAFF, MAIL CODE 482-C23-B21, P O BOX 300, DETROIT, MI, 48265-3000, US

(21) Appl. No.: 11/039,571

(22) Filed: Jan. 20, 2005

(51) Int. Cl. C23C 16/00; B05D 3/00

(52) U.S. Cl. 427/249.7; 427/299

(57) ABSTRACT

A process for cleaning and coating CVT bands includes a precleaning step, an argon sputtering step, a bond layer deposition step, and a final layer deposition.

### TECHNICAL FIELD

This invention relates to methods for properly coating components for improved wear resistance and, more particularly, to properly making wear-resistant belts for continuously variable transmissions (CVT).

### BACKGROUND OF THE INVENTION

Many current continuously variable transmissions (CVT) employ push belt technology wherein a plurality of continuous bands support elements or shoes. The elements are engaged with a pair of sheaves, one of which is movable, to provide the proper ratio between the input and output. During operation, the bands can move relative to each other and relative to the shoe elements. This movement can create noise within the CVT. This noise is generally termed “belt shudder,” which is an objectionable vibration, and it is desired to be eliminated.

The belt shudder begins to occur after relatively minimal usage and therefore is generally unacceptable. The belt shudder is generally caused by a stick-slip phenomena, which occurs between the innermost band and the shoulder on the shoe element.

### SUMMARY OF THE INVENTION

It is an object of the present invention to provide a method of making belts or bands for the CVT with an improved process.

In one aspect of the present invention, the belts are electrosonically degreased.

In another aspect of the present invention, after degreasing the belts are rinsed in de-ionized water.

In yet another aspect of the present invention, the belts are also cleaned with a rinse of methanol.

In still another aspect of the present invention, an aqueous method can also be used to remove oil and dirt from the belts.

In yet still another aspect of the present invention, the belts are placed in a vacuum chamber on a fixture connected to a high voltage power supply.

In a further aspect of the present invention, the chamber is reduced in pressure to apply a low atmosphere and argon (Ar) is fed into the chamber.

In yet a further aspect of the present invention, the argon is placed in the chamber at approximately 15 milli-Torr.

In still a further aspect of the present invention, the belts are pulsed with a bias voltage of approximately −4 kV.

In yet still a further aspect of the present invention, the chamber has silane (SiH₄) gas introduced to replace the argon while the bias voltage remains constant.

In still yet a further aspect of the present invention, the silane (SiH₄) gas is replaced with acetylene (C₂H₂) gas while the bias voltage still remains constant.

In a yet still further aspect of the present invention, the present method deposits a diamond-like carbon coating (DCL) on the belts at a distance approximately 1-3 μm when the bias voltage is turned off and the process is completed.

### DESCRIPTION OF THE DRAWINGS

FIG. 1 is an isometric view of a conventional belt used in a continuously variable transmission.

FIG. 2 is an end view of one of the shoe elements used in a continuously variable transmission.

FIG. 3 is a diagrammatic representation of a portion of the process for making improved continuously variable transmission belts.

### DESCRIPTION OF AN EXEMPLARY EMBODIMENT

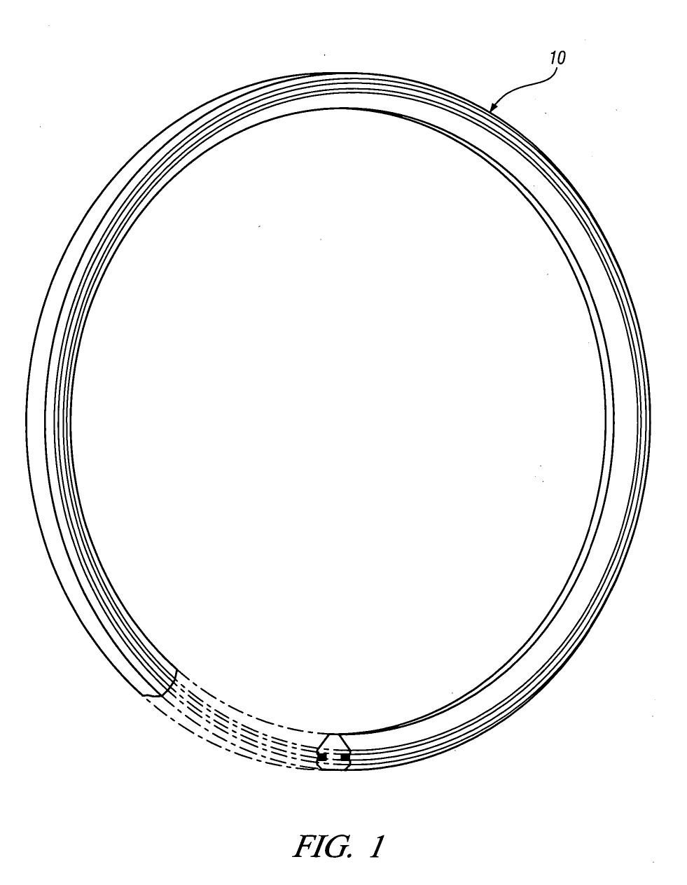

A continuously variable transmission (CVT) belt or band 10 is shown in FIG. 1 and, as those skilled in the art will recognize, the belt 10 is a continuous loop.

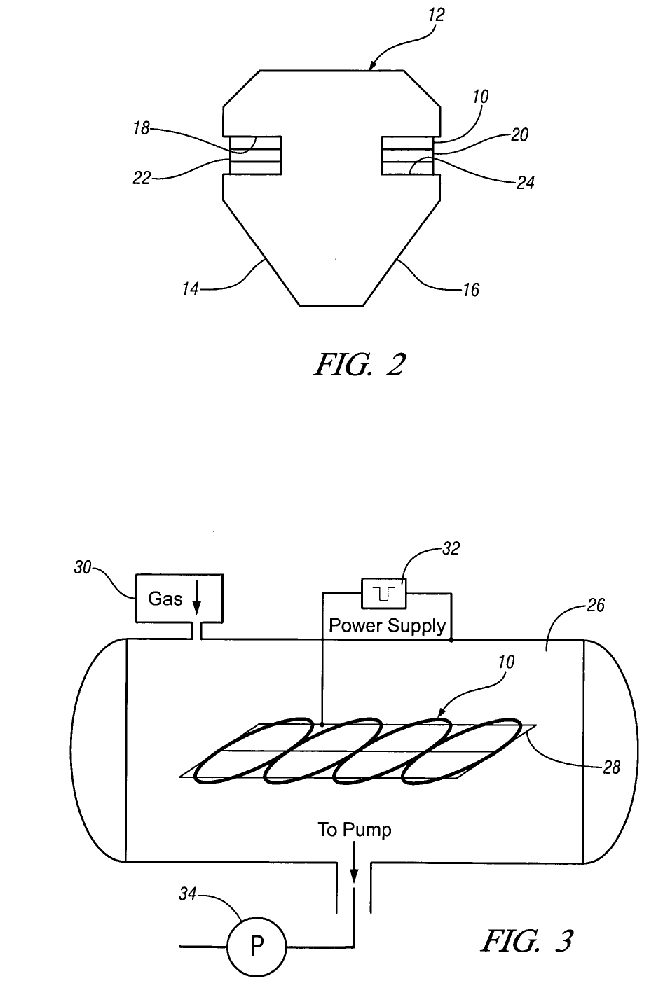

FIG. 2 represents a shoe element 12 used in the CVT. The element 12 has tapered sides 14 and 16, which are adapted to engage the driven surfaces on a conventional pulley or sheave. The shoe element 12 has a pair of slots 18 and 20 in which a plurality of bands 10 are disposed. The bands 10 are employed to maintain the shoes in proper alignment and being employed within a CVT. Under some driving conditions or power transmission conditions, the belts 10 can slip in the slots 18 and 20 such that the inner surfaces 22 and 24 of the slots will in some instances undergo a stick-slip phenomena with the inner surface of the innermost belt 10.

To reduce this stick-slip phenomena, it is desirable to process the belts 10 such that the proper surface is created on the belt 10. With the present invention, the surface is provided in what is termed a diamond-like carbon hydrogen (DLC) surface. The DLC coating is provided by a discharge plasma-enhanced chemical vapor deposition process (PECVD). This process involves several steps including: (1) precleaning of the parts prior to vacuum processing; (2) installation of parts into a vacuum chamber; (3) argon sputtering; (4) bond layer deposition; (5) diamond-like carbon deposition; and (6) removal of parts from the vacuum chamber.

FIG. 3 is a diagrammatic representation of the PECVD system and includes a vacuum chamber 26, a fixture 28 on which the bands 10 are placed, a gas supply system 30, a power supply 32, and a vacuum pump 34.

The coating process requires that the parts be ultrasonically degreased preferably in a 5% solution of industrial degreaser and a 5% solution of another industrial cleaner at 55° C. The CVT bands 10 are rinsed in de-ionized water after each thirty-minute cleaning step. A final cleaning is achieved by rinsing the CVT band 10 with copious amounts of methanol. An aqueous method can also be used to remove the oil and dirt.

The CVT bands 10 are installed in the vacuum chamber 26 on the fixture 28 that is connected to the high voltage power supply 32. After the bands 10 are in place, the pressure in chamber 26 is reduced by the vacuum pump 34. The operating atmosphere for the process is preferably below 2×10⁻⁵ Torr. When this atmosphere condition is reached, argon gas (Ar) is fed into the chamber to a pressure of approximately 15 milli-Torr. A bias pulse voltage is applied to the parts through the fixture 28. The bias voltage is preferably −4 kV at 2000 Hz. The pulse width of the applied voltage is approximately 20 μsec. The negative pulse voltage results in a glow discharge surrounding the parts and drives the ions from the plasma to the parts.

During this portion of the operation, argon sputtering occurs and as a result surface oxides, which cannot be cleansed in the precleaning process are removed. After argon sputtering, silane (SiH₄) gas is introduced into the vacuum chamber 26 and the argon is gradually withdrawn while the bias voltage remains constant. A bond layer of silicon (Si) is deposited on each of the belts 10. When the desired bond layer thickness preferably 0.1 to 0.2 μm is reached, acetylene gas (C₂H₂) is gradually introduced and the silane (SiH₄) is turned off or withdrawn while the bias voltage remains constant.

In the presence of the acetylene gas (C₂H₂), a DLC coating is deposited on the parts. When the desired coating thickness is reached, typically 1-3 μm, the bias voltage is turned off, the process is completed, and the belts 10 are removed from the vacuum chamber after the chamber has been returned to atmospheric pressure.

It should be noted that the initial bond layer of silicon (Si) can be SiC, Si₃N₄, or SiₓN_{y}. These layers are formed using silane (SiH₄) plus acetylene (C₂H₂), or methane (CH₄), methylsilane (CH₃)SiH₃, dimethylsilane (CH₃)₂SiH₂, trimethylsilane (CH₃)₃SiH, and tetramethylsilane (CH₃)₄Si. The DLC can be formed using acetylene (C₂H₂), methane (CH₄), or other carbonaceous gases. The DLC can also contain other elements such as silicon (Si) or metals such as tungsten (W), chrome (Cr), or titanium (Ti) for enhanced wear resistance.

The surface reference before and after the DLC deposition was measured using an optical profilometer. The band 10 surface average roughness Rₐ has 0.47 to 0.59 μm. The coating hardness is in the range of 1500-3000 Hᵥ, which is much harder than the substrate of the belt 10. Because the coating is thin and is deposited via PECVD, it has a much stronger bonding to the substrate of the belt 10 than other types of coatings, such as plating and thermal spray.

1. A method of making a wear-resistant continuously variable transmission belt comprising the steps of:
(1) precleaning said belt;
(2) installing said belt in a chamber and producing a vacuum in said chamber;
(3) sputtering a surface of said belt with argon;
(4) depositing a first layer on said belt;
(5) depositing a diamond-like carbon layer on said belt; and
(6) removal of said belt from said vacuum chamber.

2. A method of making a wear-resistant continuously variable transmission belt comprising the steps of:
(1) precleaning said belt in a degreasing solution and in an industrial cleaner solution at 55° C.;
(2) rinsing said continuously variable transmission belt after each cleaning step;
(3) cleaning said belt with copious amounts of methanol;
(4) placing said belt in a vacuum chamber and reducing the pressure therein to a predetermined value;
(5) introducing argon into said chamber at a predetermined pressure;
(6) pulsing said chamber and said belt with a bias voltage having a predetermined voltage level cycle and cycle time;
(7) introducing silane gas into said vacuum chamber and cleaning off said argon gas while said bias voltage remains constant;
(8) introducing acetylene gas into said chamber and reducing or withdrawing said silane gas while said bias voltage remains constant;
(9) maintaining said acetylene gas until a diamond-like carbon hydrogen coating is deposited on said bands to a thickness in the range of 1-3 μm;
(10) removing said bias voltage and removing said belt from said vacuum chamber.
